(19) United States
(12) Patent Application Publication
(10) Pub. No.: US 2008/0023726 A1
(43) Pub. Date: Jan. 31, 2008

(54) Schottky gate metallization for semiconductor devices

(76) Inventors: Ilesanmi Adesida, Champaign, IL (US); Seiyon Kim, Portland, OR (US); Liang Wang, Urbana, IL (US)

Correspondence Address: MARTIN NOVACK, 16355 VINTAGE OAKS LANE, DELRAY BEACH, FL, 33484, US

(21) Appl. No.: 11/805,855

(22) Filed: May 24, 2007

Related U.S. Application Data
(60) Provisional application No. 60/808,440, filed on May 24, 2006.
(60) Provisional application No. 60/808,478, filed on May 24, 2006.

(51) Int. Cl. H01L 29/739; H01L 21/28; H01L 29/80; H01L 21/338

(52) U.S. Cl. 257/194; 257/280; 438/172; 438/572; 438/580; 257/E29.178; 257/E29.246; 257/E21.45; 257/E21.452

(57) ABSTRACT

A method of forming a Schottky barrier contact to a semiconductor material, includes the following steps: depositing an iridium contact on a surface of the semiconductor material; and annealing the iridium contact to form a Schottky barrier contact to the semiconductor material. For an example of an iridium Schottky contact on an InAlAs semiconductor material, the annealing temperature is preferably in the range about 350° C. to 500° C.

### RELATED APPLICATIONS

Priority is claimed from U.S. Provisional Patent Application No. 60/808,440, filed May 24, 2006, and U.S. Provisional Patent Application No. 60/808,478, filed May 24, 2006, and both said U.S. Provisional Patent Applications are incorporated herein by reference. The subject matter of the present Application is related to subject matter disclosed in copending U.S. patent application Ser. No. ________ (File UI-TF-06074), filed of even date herewith, and assigned to the same assignee as the present Application.

### GOVERNMENT RIGHTS

This invention was made with Government support under Contract Number ANI-0121662 awarded by the National Science Foundation (NSF) and Contract Number N00014-01-1-0018 awarded by Office of Naval Research (ONR). The Government has certain rights in the invention.

### FIELD OF THE INVENTION

This invention relates to the field of semiconductor devices and methods and, more particularly, to Schottky barrier contacts for semiconductor devices, and the fabrication thereof. The invention also related to field effect transistor devices and the fabrication thereof.

### BACKGROUND OF THE INVENTION

A primary property of a non-ohmic metal-semiconductor interface is its Schottky barrier height; that is, the height of the rectifying energy barrier for electrical conduction across the metal-semiconductor junction. An important practical aspect of Schottky barrier height is in gate metallization of field-effect devices, and one application of interest herein is gate metallization of high electron mobility transistors (HEMTs) or heterostructure field effect transistors (HFETs).

The InAlAs/InGaAs/InP HEMT is considered to be one of the most promising devices for high speed digital circuits, millimeter and submillimeter applications due to its superior high frequency and low noise capabilites. Gate metallization plays a vital role in determining the operation parameters of InAlAs/InGaAs/InP HEMTs. Enhancement-mode HEMTs (E-HEMTs) are desirable for use in conjunction with depletion mode HEMTs (D-HEMTs) in simplifying circuit design and reducing power consumption. While high performance has been more readily achieved in D-HEMTs, it is challenging to fabricate E-HEMTs exhibiting high performance and thermal stability. The realization of E-HEMTs relies chiefly on-the high Schottky barrier height (φ_{B}) Of the gate metals to deplete the channel and to obtain positive threshold voltage (Vth). Also, a high φ_{B} reduces the gate leakage current. For these reasons, φ_{B} of several metals on InAlAs has been investigated. Among these have been:

Titanium (see N. Harada, S. Kuroda, T. Katakami, K. Hikosaka, T. Mimura, and M. Abe, In IEEE Proc. 2nd Int. Conf. InP and Related Mater., 1991 Cardiff, Wales UK; A. Mahajan, M. Arafa, P. Pay, C. Caneau, and I. Adesida, IEEE Transactions on Electron Devices 45, 2422 1998; and L. P. Sadwick, C. W. Kim, K. L. Tan, and D. C. Streit, IEEE Electr. Device Lett. 12, 626,1991);

Platinum (see N. Harada et al. 1991, supra; A. Mahajan et al., 1998, supra; L. P. Sadwick et al., 1991, supra; A. Fricke, G. Stareev, T. Kummetz, D. Sowada, J. Mahnss, W. Kowalsky, and K. J. Ebeling, Appl. Phys. Left. 65, 755, 1994; S. Kim, I. Adesida, and H. Hwang, Appl. Phys. Lett. 87, 2005; and M. Dammann, A. Leuther, R. Quay, M. Meng, H. Konstanzer, W. Jantz, and M. Mikulla, Microelectron. Reliab. 44, 939, 2004);

Palladium (see N. Harada et al., 1991, supra; A. Mahajan et al. 1998, supra; and H. F. Chuang, C. P. Lee, C. M. Tsai, D. C. Liu, J. S. Tsang, and J. C. Fan, J. Appl. Phys. 83, 366, 1998);

Aluminum (see N. Harada et al. 1991, supra; A. Mahajan et al., 1998, supra; and S. J. Pilkington, and M. Missous, J. Appl. Phys. 83, 5282, 1998),;

Chromium (see N. Harada et al., 1991, supra); and

Gold (see L. P. Sadwick et al., 1991, supra; and S. J. Pilkington et al., 1998, supra).

Among the foregoing-elemental candidates, Pt has the highest φ_{B} of over 800 meV after annealing and is frequently used as buried gates. Thermal treatment at 200-300° C. is usually needed for Pt to enhance φ_{B} and to stabilize the gates. In-diffusion of Pt in InAlAs during thermal treatment reduces the effective gate-to-channel layer distance. It has been shown in several systems that this reduction in the gate-to-channel distance could be used to further increase Vth (see A. Mahajan et al. 1998, supra; Y. Takanashi, T. Ishibashi, and T. Sugeta, IEEE Tran. Electron Dev. 30, 1597, 1983; and M. G. Fernandes, C. C. Han, W. Xia, s.S. Lau, and S. P. Kwik, J. Vac. Sci. Technol. B 6,1768, 1988). In the Pt-HEMT system a positive shift of about 240 meV in Vₜₕ was observed which is essential in achieving E-HEMTs (see A. Mahajan et al. 1998, supra). Nonetheless, the rapid diffusion of Pt in InAlAs poses a potential threat to the reliable performance of the devices (see S. Kim et al., 2005, supra; M. Dammann et al. 2004, supra; and C. Canali, F. Castaldo, F. Fantini, D. Ogliari, L. Umena, and E. Zanoni, IEEE Electr. Device Lett. 7, 185, 1986).

Kim et al. showed that a metastable amorphous interlayer formed at the Pt/InAlAs interface due to the diffusion of Pt. The a-layer consumed up to 70% of the InAlAs barrier layer during prolonged thermal treatment at a low temperature of 250° C. The substantial shortening in the gate-to-channel distance brings considerable changes to the operational parameters of the devices such as transconductance and gate capacitance, or can even cause device failure (see S. Kim et al., 2005, supra; and M. Dammann et al., 2004, supra). Since it is preferable to have a metallization that is stable after the device is fabricated, the low optimum annealing temperature, fast diffusivity, and thus low thermal stability of Pt, are serious drawbacks to its use for Schottky contacts.

It is among the objects of the present invention to provide improved Schottky barrier contacts and techniques for fabrication of same which overcome problems and limitations of prior art approaches, including those summarized above. It is also among the objects of the present invention to provide improved field effect devices and HEMTs, and methods for making same.

### SUMMARY OF THE INVENTION

A form of the invention is directed to a method of forming a Schottky barrier contact to a semiconductor material, including the following steps: depositing an iridium contact on a surface of the semiconductor material; and annealing the iridium contact to form a Schottky barrier contact to said semiconductor material. In one preferred embodiment of this form of the invention, the semiconductor material is a III-V semiconductor material, which, in an illustrated embodiment, is InAlAs. The annealing temperature is preferably in the range about 350° C. to 500° C., an annealing temperature of about 475° C. being employed in an illustrated embodiment. In a disclosed embodiment of this form of the invention, the Schoftky barrier height of the Schottky barrier contact is at least about 800 meV. Also in this embodiment, at least one further metal is deposited over the iridium contact. The iridium contact is applied at a thickness sufficient to prevent diffusion of said at least one further metal into the semiconductor surface below the iridium contact. Prior to annealing, the contact can be passivated with Si₃N₄ or SiNₓ.

Another form of the invention is directed to a field-effect device, comprising: a layered semiconductor structure that includes a channel layer and at least one layer over the channel layer; spaced apart source and drain contacts disposed over said at least one layer and communicating with the channel layer; and an iridium gate, between the source and drain contacts, forming a Schottky barrier contact on said at least one layer. In an embodiment of this form of the invention, said at least one layer includes a layer of InAlAs, and the iridium gate is deposited on the InAlAs layer to form a Schottky barrier contact on the InAlAs layer. The gate can comprise at least one further metal layer disposed on the iridium gate. As one example, the iridium gate can further include titanium, platinum, and gold over the iridium, thereby comprising an Ir/Ti/Pt/Au gate.

In accordance with a further form of the invention, there is provided a high electron mobility field-effect transistor device, comprising: a layered semiconductor structure that includes an InGaAs channel layer and at least one layer over the channel layer, said at least one layer including an InAlAs layer; spaced apart source and drain contacts disposed over said at least one layer and communicating with the channel layer; and an iridium gate, between said source and drain contacts, deposited on the InAlAs layer, forming a Schottky barrier contact on the InAlAs layer. Means are provided for applying electrical potentials with respect to said drain, source, and gate contacts. In an embodiment of this form of the invention, said at least one layer includes an InGaAs cap layer disposed over part of the InAlAs layer, and source and drain contacts are deposited as silver-based contacts on the InGaAs cap layer. As described in the above-referenced copending U.S. patent application Ser. No. ______, filed of even date herewith and assigned to the same assignee as the present Application, the silver-based source and drain contacts can be formed by depositing layers of germanium, silver and nickel, thereby forming Ge/Ag/Ni source and drain contacts.

Further features and advantages of the invention will become more readily apparent from the following detailed description when taken in conjunction with the accompanying drawings.

### BRIEF DESCRIPTION OF THE DRAWINGS

FIG. 1 shows a simplified layer structure of a Schottky diode of a type used in examples of an embodiment of the invention.

FIG. 2 is a graph of the I-V characteristic of iridium Schottky contacts, for contacts as-deposited and for contacts anaealed at 475° C. for 30 seconds.

FIG. 3 is a Richardson plot of iridium Schottky contacts from I-V-T measurements.

FIG. 4 is a graph showing Schottky barrier height (on the left vertical axis) and ideality factor (on the right vertical axis) for iridium and platinum contacts.

FIG. 5 shows, in cross-section an example of a high electron mobility transistor which can employ an embodiment of the invention.

FIG. 6 shows graphs of DC transfer characteristics of E-HEMTs having an Ir/Ti/Pt Au gate (graphs of FIG. 6a) and Pt/Ti/Pt/Au (graphs of FIG. 6b), before annealing and after annealing.

FIG. 7 shows graphs of gate length dependence of threshold voltage and unity current gain cutoff frequency of Ir/Ti/Pt/Au gate HEMTs before and after annealing.

FIG. 8 shows the layer structure of a further example of high electron mobility transistors in which embodiments of the invention can be utilized.

### DETAILED DESCRIPTION

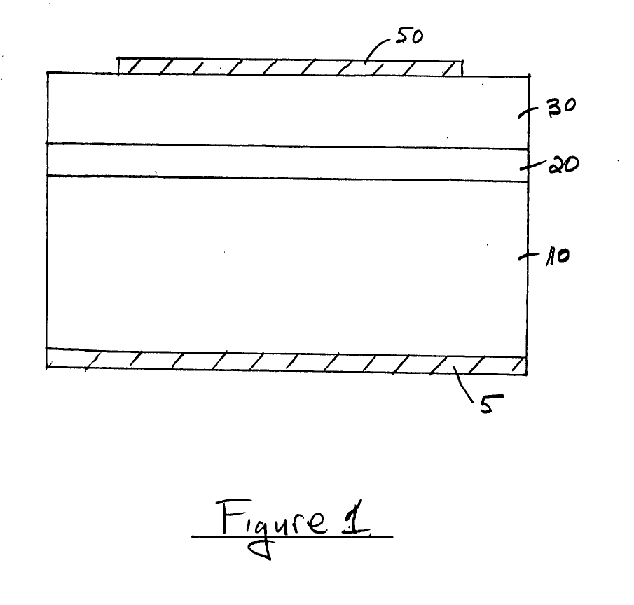

The layer structure used to fabricate Schottky diodes (see FIG. 1) for an example hereof was grown by molecular beam epitaxy (MBE) on an n⁺ InP substrate 10. From the bottom up, the structure included a 0.1 μm thick n⁺ (1×10¹⁸ cm⁻³) InAlAs buffer layer 20 followed by a 0.9 μm-thick, lightly doped InAlAs (n=1×10¹⁶ cm⁻³) layer 30. AuGe/Ni/Au ohmic contact 5 was formed on the backside of the InP by e-beam evaporation and alloying at 370° C. for 60 s in a furnace. 250 μm diameter, circular-shaped Schottky contacts (represented at 50) were fabricated by photolithography, e-beam evaporation and lift-off. Samples were rinsed in HCl:DI=1:2 solution to remove native oxide before metallization. Samples with 15 nm-thick Ir and Pt contacts were fabricated. Some of these samples were thermally treated at various temperatures ranging from 150 to 500° C. for 30 s in nitrogen ambient in a rapid thermal anneal system. DC I-V-T measurements were performed on the samples on a variable temperature (−43 to 120° C.) probe station using an HP 4145B semiconductor parameter analyzer.

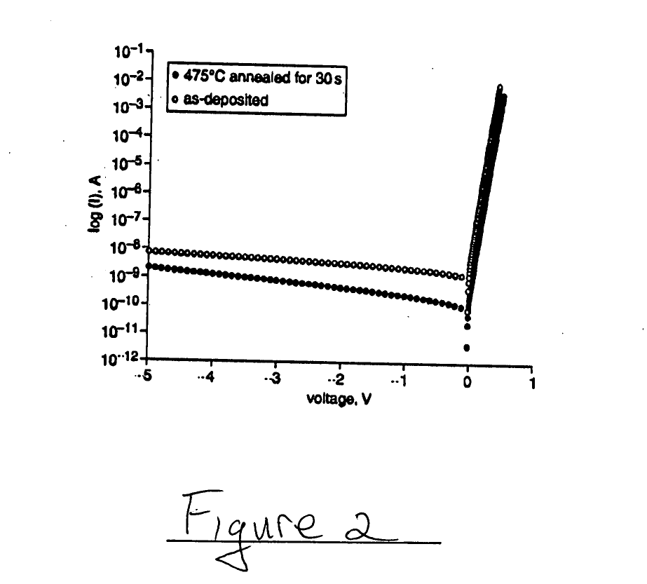

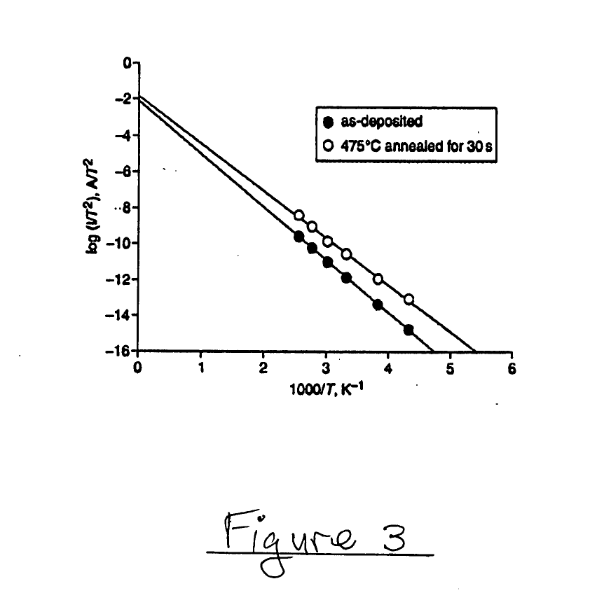

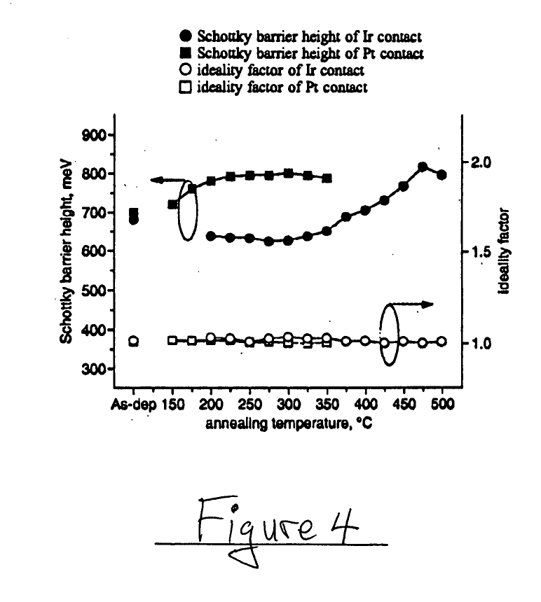

FIG. 2 shows typical DC I-V curves measured at room temperature (300 K) for the Ir contacts. Results for an as-deposited Ir sample (open circles) and a 475° C.-annealed Ir sample (solid circles) are shown in the Figure. The reverse leakage current for the annealed sample is about an order of magnitude lower than that of the as-deposited sample. This shows that there is a difference in the φ_{B}'s (Schottky barrier heights), with that for the annealed sample being higher. From I-V measurements at room temperature, the φ_{B} for the 475° C.-annealed Ir is 818 meV and that for the as-deposited Ir is 680 meV. An ideality factor (n) close to unity was measured for both the samples (see FIG. 4). I-V-T measurements conducted for the samples showed similar results. Plots of the log (I/T²) against inverse temperature for the two samples are shown in FIG. 3. The linearity of the data and the unity ideality factor indicate that the transport of carriers across the metal-semiconductor contact is by thermionic emission. These measurements were also conducted for a variety of Ir and Pt samples annealed at different temperatures. The results are summarized in FIG. 4. It is seen that the φ_{B} of as-deposited Pt is 700 meV and is slightly higher than that of as-deposited Ir at 680 meV. As the Pt/InAlAs contact is annealed at higher temperatures, φ_{B} increased up to 800 meV at 200° C. and remains constant but beyond 350° C., there is a catastrophic decrease in φ_{B} and it becomes very non-uniform from device to device. For Ir/InAlAs, there is a slight decrease from 680 meV for the as-deposited sample to 630 meV for 275° C.-annealed Ir. Beyond that there is a monotonic increase until a maximum of 818 meV is reached at 475° C. Above 500° C., the samples became unstable and backside ohmic contacts became visibly degraded. For all measurements within the temperature range shown in FIG. 4, ideality factors were near unity.

The underlying factors responsible for the trends shown in FIG. 4 include interfacial reactions between the metals and InAlAs. From FIG. 4, it is deduced that Pt is driven to the final reaction phase much more rapidly than Ir. At 200° C., Pt has achieved its highest φ_{B} while the highest φ_{B} is obtained for Ir at 475° C. For Ir, if a sample is first annealed at 275° C., its φ_{B} can be elevated by further annealing at 475° C. However, once a sample is annealed at 475° C., its φ_{B} is stable when annealed further at lower temperatures. Therefore, it can be deduced that Ir is more stable than Pt at higher temperatures. Previous investigations on interfacial reactions for thermally-treated Ir/GaAs (see Sands, T., Keramidas, V. G., Yu, K. M., Washburn, J., and Krishnan, K., J. Appl. Phys., 1987, 62, (5), pp. 2070-2079; Yu, K. M., Sands, T., Jaklevic, J. M., and Haller, E, J. Appl. Phys., 1987, 51, (3), pp. 189-191; and Shultz, K. J., Musbah, O. A. and Chang, Y. A., J. Appl. Phys., 1990, 67, (II), pp. 6798-6806); and Pt/GaAs (see Sinha, A. K., and Poate, J. M., Appl. Phys. Lett., 1973, 23, (12), pp. 666-668; Fontain, C., Okumura, T., and Tu, K. N., J. Appl. Phys., 1983, 54, (3), pp. 1404-1412; and Ko, D. H. and Sinclair, R., J. Appl. Phys., 1992, 72, (5), pp. 2036-2042), have been reported. For the Ir/GaAs system, Yu et al. (1987, supra) and Schulz et al. (1990, supra) suggested that IrₓGa_{y}/IrAs₂ formed by Ga—Ir inter-diffusion is the final stage of reaction with IrAs₂ being the abundant material at the interface. Similar conclusions were obtained by Ko et al. (1992, supra) for the Pt/GaAs system where PtAs₂ was detected as the interfacial material. Therefore, PtAs₂ and IrAs₂ may have higher work functions than the pure metals, hence, the increase in Schottky barrier heights. Similar reactions may occur for these metals on InAlAs forming IrAs₂ and PtAs₂, although further investigation would be needed to determine the reaction mechanisms and to identify the final products.

From the foregoing example, it will be recognized that Schottky barrier height is enhanced by annealing at temperatures above about 375° C. with a maximum of 818 meV achieved at 475° C. This is comparable to the 800 meV obtained for annealed Pt contact on InAlAs which is obtained at temperatures above 200° C. The higher temperature required for Ir annealing indicates that Ir will form a thermally stable gate metal in InAlAs/InGaAs HEMTs.

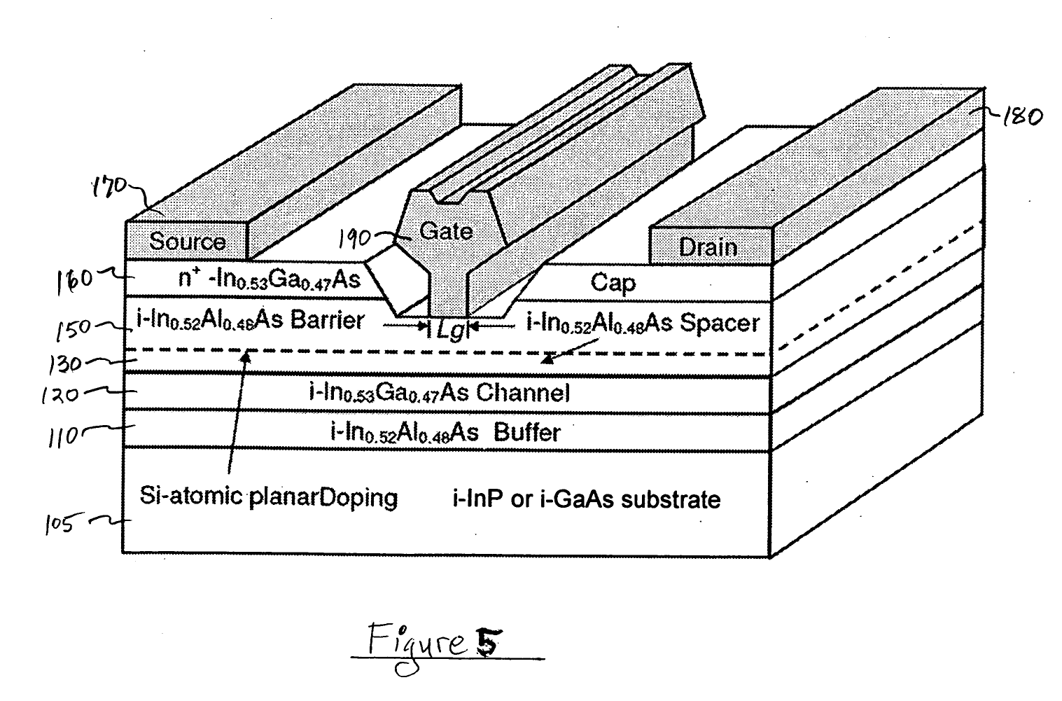

FIG. 5 shows, in cross-section, an example of a type of device that can be utilized in practicing a form of the invention. The device of FIG. 5 is a high electron mobility transistor (HEMT), which, in this example, is a field-effect HEMT formed on an indium phosphide substrate or gallium arsenide substrate 105 (therefore commonly called an InP HEMT or GaAs metamorphic HEMT) on which is deposited an insulating In_{0.52}Al_{0.48}As buffer layer. In this diagram, there is shown an undoped In_{0.53}Ga_{0.47}As channel layer 120, and, over this layer, a spacer layer 130 of undoped In_{0.52}Al_{0.48}As, a thin Si-atomic planar doping region, and an undoped In_{0.52}Al_{0.48}As barrier layer 150, and, except in the notched central region, a heavily doped n-type In_{0.53}Ga_{0.47}As cap layer 160. Spaced apart source 170 and drain 180 ohmic contacts are formed on the n+ In_{0.53}Ga_{0.47}As cap layer 160, and the gate 190, which is shown as a T-gate in this example, is formed with a Schontky barrier contact of length L_{g} on the In_{0.52}Al_{0.48}As barrier layer 150.

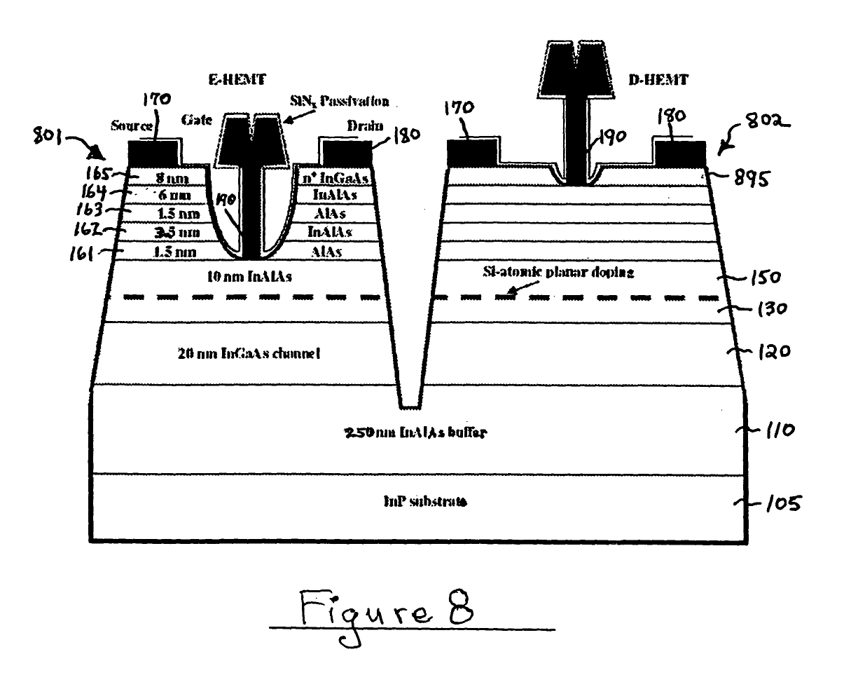

In accordance with a further embodiment there is set forth a gate metallization, e.g. for the type of device shown in FIG. 5, that has high barrier height and also has low diffusivity. In an example of this embodiment In_{0.52}Al_{0.48}As/In_{0.53}Ga_{0.47}As/InP E-HEMTs with Ir/Ti/Pt/Au and Pt/Ti/Pt/Au gates were fabricated. The HEMT structure was designed for two different recess etching depths in order to achieve the integration of enchancement- and depletion-mode (E/D) HEMT devices (see A. Mahajan et al. 1998, supra). In this regard, reference can be made to the diagram of FIG. 8, which shows, on the left, the enhancement mode device 801, and, on the right, the depletion mode device 802, of the integrated structure. The layers 105, 110, 120, 130, and 150 are similar to their counterparts in FIG. 5. The heterostructure on InP substrate 105 includes, in this case, a 250 nm InAlAs buffer 110, a 20 nm InGaAs channel 120 a 4 nm InAlAs spacer 130, Si atomic planar doping, a 6 nm InAlAs E-Schottky layer, a 1.5 nm AlAs first etch stop layer 161, a 3.5 nm InAlAs first barrier layer 162, a 1.5 nm AlAs second etch stop layer 163, a 6 nm InAlAs second barrier layer 164, and an 8 nm n⁺-InGaAs cap layer 165. Hall effect measurement yielded an electron sheet concentration of 8.68×10¹¹ cm⁻² and a mobility of 7130 cm²/V·s for the heterostructure with the n⁺-cap layer removed. For device fabrication, isolation was achieved by mesa etching in a citric acid/hydrogen peroxide solution. Alloyed AuGe/Ni/Au ohmic contacts were then formed with a typical contact resistance of 0.15Ω·mm. After the deposition of Ti/Pt/Au overlay metal, T-gates were formed in PMMA/PMMA-MAA/PMMA trilayer resist using the JEOL 6000FS electron beam lithography nanowriter system. Gate recess eteching was performed for E-HEMT devices with citric acid: H₂O₂=20:1 solution and the AlAs etch stop was removed using HCl: D1 water=1:2 solution. Finally, Ir/Ti/Pt/Au (5/15/10/170 nm) and Pt/Ti/Pt/Au (5/15/10/170 nm) were evaporated for the T-gate metallizations. Devices with various gate lengths from 0.25 to 0.4 μm were fabricated. DC and RF characteristics were measured with a HP 4142B semiconductor parameter analyzer and HP 8510C network analyzer, respectively. To investigate the effect of gate annealing, the measurements were repeated after the devices were treated in a rapid thermal annealing (RTA) system at 250° C. for 30 s.

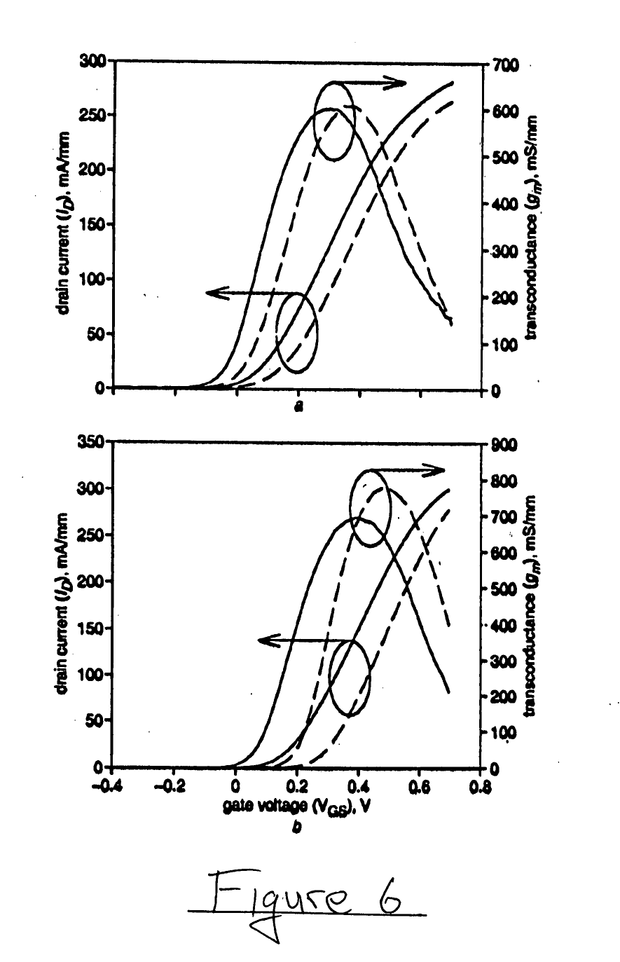

The DC transfer characteristics of 0.25 μm gate eHEMTs with Ir/Ti/Pt/Au and Pt/Ti/Pt/Au gates are shown in FIGS. 6a and 6b, respectively. The maximum drain currents (I_{Dmax}) and maximum extrinsic transconductances (g_{m,max}) of all the devices measured ranged from 300 to 350 mA/mm (V_{GS}=0.7V, V_{DS}=2V) and from 600 to 700 mS/mm, respectively. A threshold voltage (V_{T}) of 85 mV and an I_{DSS} of 4.7 mA/mm at V_{DS}=1V were obtained for Ir/Ti/Pt/Au gate HEMTs without gate annealing. For these Ir-based devices, excellent e-mode characteristics of V_{T} of 134 mV with 1_{DSS} of 1.3 mA/mm at V_{DS}=1V were realized after the gate anneal. No change in g_{m,max} was observed due to thermal treatment. For Pt/Ti/Pt/Au gate eHEMTs, V_{T} increased from 150 mV before annealing to 295 mV after annealing. This large shift in V_{T} was accompanied by a significant increase in g_{m,max}. An increase in g_{m,max} from 700 to 784 mS/mm was measured, which translates to a 12% increase. From the results, it is observed that Ir/Ti/Pt/Au gate devices were more stable than conventional Pt/Ti/Pt/Au gate devices in terms of V_{T} and gₘ. A positive shift in V_{T} that is activated by thermal annealing can be attributed to two effects. These are Schottky barrier height enhancement and gate metal diffusion (Mahajan et al. 1995, supra). It is known that the Schottky barrier height of Pt on InAlAs increases by ˜100 mV owing to thermal treatment at moderate temperatures (Harada et al., 1991, supra; Mahajan et al., 1994, supra). Since g_{m.max} is related to the effective thickness of the InAlAs Schottky layer (d_{eff}) by:

$${g}_{m , int}^{max} = \frac{{ɛ}_{C} {v}_{S} W}{{d}_{eff}}$$

(see Morkoc, H., UnIu, H., and Ji, G.: “Principles and Technology Of MODFETs” (John Wiley & Sons Ltd. 1991), Vol. 2, pp. 383-387), the enhancement of gₘ indicates the d_{eff} is reduced owing to gate metal diffusion. No significant change in contact resistance was observed after thermal treatment. Thus, it can be deduced that both Schottky barrier enhancement and metal diffusion occurred in the Pt-based devices owing to gate annealing. In addition, it can be deduced that Ir has significantly less diffusivity than Pt, indicating a higher thermal stability for Ir gate contact.

The RF performances of both types of devices have been measured. The f_{T}'s and fₘₐₓ of 0.25 μm gate Ir-based devices before annealing were 85 and 210 GHz, respectively. The corresponding results for Pt-based devices were 90 and 220 GHz, respectively. No significant changes were observed in these performances because of annealing. With a constant f_{T} and considering that

$${f}_{T} = \frac{{g}_{m , max}}{{C}_{gs}}$$

(Morkoc et al., 1991, supra) it is then noted that the gate capacitance of Pt/Ti/Pt/Au gate devices increased, thereby compensating the increase of g_{m,max}. The increase in gate capacitance (C_{gs}) originated from the reduction of the Schottky layer thickness owing to Pt diffusion. Although the RF performances of the Pt-based devices did not deteriorate, the increase in gate capacitance will affect circuit performances by increasing delay times for charging and discharging the gates. This can cause speed problems in complex digital circuits with large fan-out. There is no evidence of gate capacitance increase in Ir/Ti/Pt/Au gate devices because gₘ and f_{T} were not altered as a result of thermal annealing. This provides evidence that the diffusion of the Ir-based gate is negligible, and further, it shows that Ir/Ti/Pt/Au eHEMT digital devices should be superior for circuit applications.

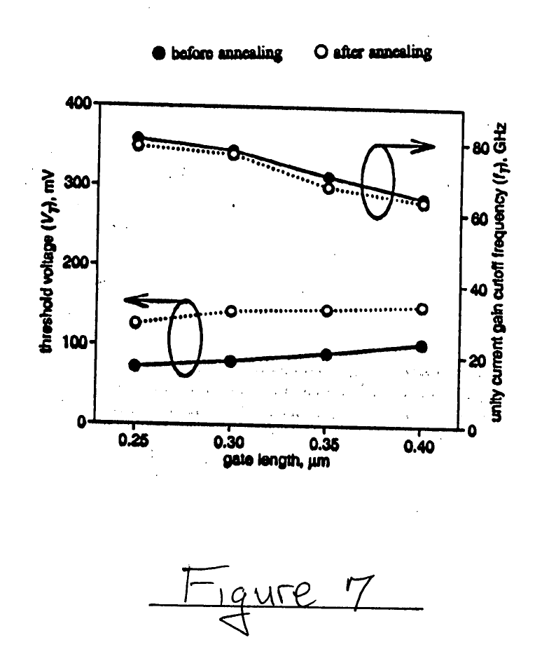

FIG. 7 shows V_{T} and f_{T} for Ir/Ti/Pt/Au gate devices with various gate lengths ranging from 0.25 to 0.4 μm before annealing (solid circles) and after annealing (open circles). Gate annealing increased V_{T} by about 40 mV for all devices whereas fₜ's were not significantly altered.

1. A method of forming a Schottky barrier contact to a semiconductor material, comprising the steps of:
depositing an iridium contact on a surface of the semiconductor material; and
annealing the iridium contact to form a Schottky barrier contact to said semiconductor material.

2. The method a defined by claim 1, wherein said semiconductor material is a III-V semiconductor material.

3. The method as defined by claim 2, wherein said semiconductor material is InAlAs.

4. The method as defined by claim 1, wherein said annealing temperature is in the range about 350° C. to 500° C.

5. The method as defined by claim 3, wherein said annealing temperature is in the range about 350° C. to 500° C.

6. The method as defined by claim 1, wherein said annealing temperature is about 475° C.

7. The method as defined by claim 1, wherein said semiconductor material is InAlAs and said annealing temperature is about 475° C.

8. The method as defined by claim 1, wherein said semiconductor material is InAlAs and said annealing temperature is about 400° C., and wherein the Schottky barrier height of said Schottky barrier contact is at least about 800 meV.

9. The method as defined by claim 1, further comprising passivating said contact, prior to annealing, with Si₃N₄ or SiNₓ.

10. The method as defined by claim 1, further comprising applying at least one further metal over said iridium contact.

11. The method as defined by claim 9, wherein said iridium contact is applied at a thickness sufficient to prevent diffusion of said at least one further metal into said semiconductor surface below said iridium contact.

12. A field-effect device, comprising:
a layered semiconductor structure that includes a channel layer and at least one layer over the channel layer;
spaced apart source and drain contacts disposed over said at least one layer and communicating with said channel layer; and
an iridium gate, between said source and drain contacts, forming a Schoitky barrier contact on said at least one layer.

13. The field-effect device as defined by claim 12, wherein said at least one layer includes a layer of InAlAs, and wherein said iridium gate is deposited on said InAlAs layer to form a Schottky barrier contact on said InAlAs layer.

14. The field-effect device as defined by claim 13, wherein said gate comprises at least one further metal layer disposed on said iridium gate.

15. The field-effect device as defined by claims 12, wherein said iridium gate further includes titanium, platinum, and gold, over said iridium, thereby comprising an Ir/Ti/Pt/Au gate

16. The field-effect device as defined by claim 12, further comprising means for applying electrical potentials with respect to said drain, source, and gate.

17. The device as defined by claim 16, wherein electrical current flow between said source and drain contacts is controlled by the electrical potential applied to said gate.

18. A high electron mobility field-effect transistor device, comprising:
a layered semiconductor structure that includes an InGaAs channel layer and at least one layer over the channel layer, said at least one layer including an InAlAs layer;
spaced apart source and drain contacts disposed over said at least one layer and communicating with said channel layer; and
an iridium gate, between said source and drain contacts, deposited on said InAlAs layer, forming Schottky barrier contact.

19. The device as defined by claim 18, wherein said gate comprises at least one further metal layer disposed on said iridium gate.

20. The device as defined by claim 18, wherein said iridium gate further includes titanium, platinum, and gold, over said iridium, thereby comprising an Ir/Ti/Pt/Au gate.

21. The device as defined by claim 18, wherein said at least one layer includes an InGaAs cap layer disposed over part of said InAlAs layer, and wherein said source and drain contacts are deposited on said InGaAs cap layer.

22. The device as defined by claim 18, further comprising means for applying electrical potentials with respect to said drain, source, and gate contacts.

23. A method of making a high electron mobility field-effect transistor device, comprising the steps of:
providing a layered semiconductor structure that includes an InGaAs channel layer and at least one layer over the channel layer, said at least one layer including an InAlAs layer;
depositing spaced apart source and drain contacts over said at least one layer; and
depositing an iridium gate, between said source and drain contacts, on said InAlAs layer, to form a Schottky barrier contact on said InAlAs layer.

24. The method as defined by claim 23 wherein said step of depositing an iridium gate, between said source and drain contacts, on said InAlAs layer, to form a Schottky barrier contact on said InAlAs layer comprises annealing the iridium contact to form said Schottky barrier contact.

25. The method as defined by claim 24, wherein said annealing temperature is in the range about 350° C. to 500° C.

26. The method as defined by claim 23, further comprising depositing at least one further metal layer on said iridium gate.

27. The method as defined by claim 23, further comprising depositing layers of titanium, platinum, and gold, over said iridium, thereby forming an Ir/Ti/Pt/Au gate.

28. The method as defined by claim 23, wherein said at least one layer includes an InGaAs cap layer disposed over part of said InAlAs layer, and wherein said source and drain contacts are deposited as silver-based contacts on said InGaAs cap layer.

29. The method as defined by claim 29, wherein said silver-based source and drain contacts are formed by depositing layers of germanium, silver and nickel, thereby forming Ge/Ag/Ni source and drain contacts.
